(19) United States
(12) Patent Application Publication
(10) Pub. No.: US 2008/0090323 A1
(43) Pub. Date: Apr. 17, 2008

(54) IMAGE SENSOR AND METHOD OF FABRICATING THE SAME

(75) Inventor: Yi-Tyng Wu, Chiayi City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNITED MICROELECTRONICS CORP., Hsinchu (TW)

(21) Appl. No.: 11/549,108

(22) Filed: Oct. 12, 2006

(51) Int. Cl. H01L 21/00; H01L 31/113

(52) U.S. Cl. 438/70; 257/290; 257/440

(57) ABSTRACT

An image sensor is provided. The image sensor includes a plurality of photodiode doped regions in a substrate, a passivation layer above the substrate, a dielectric layer between the passivation layer and the substrate, and a plurality of color filters in the dielectric layer being corresponding to the photodiode doped regions.

### BACKGROUND OF THE INVENTION

1. Field of the Invention

The present invention relates to a sensor and a method of fabricating the same. More particularly, the present invention relates to an image sensor and a method of fabricating the same.

2. Description of Related Art

Image sensors are devices for converting optical information into electric signals. The image sensors can be substantially classified into picture tubes and fixed image pick-up apparatus. Currently, a fixed image pick-up apparatus includes a charged coupled device (CCD) and a complementary metal oxide semiconductor (CMOS) image sensor.

The method of driving the CMOS image sensor is simple and convenient, and can accomplish a plurality of scanning manners, and signal processing circuits can be fabricated into a single chip. Also, the method can accomplish small volume products, and is also compatible with CMOS technique, thus saving manufacturing cost and reducing power consumption. Therefore, the CMOS image sensor can be widely applied to low-order image products such as security monitors, digital cameras, toys, mobile phones, and image phones.

However, a color filter (CF) of the conventional CMOS image sensor is made of organic material which has a low melting point approximately less than 300° C. Therefore, the color filter is usually formed above the passivation layer after the metal interconnect is formed, so as to avoid being melted under high temperature of the process. Since light rays can be received by the photodiode only after passing through the passivation layer and the metal interconnect rather than being directly transmitted to the photodiode after passing through the color filter, the light rays may be absorbed by film layers such as dielectric layers or passivation layers. Thus, the light transmittance is low, and optical performance of the CMOS transistor image sensor is not good. In another aspect, as a gap exists between condensing lenses, the light rays may be easily scattered and directly pass through the gap and even may be irradiated on the adjacent light sensing region. Thus, a cross-talk phenomenon occurs, thus increasing the noise of CMOS image sensor.

### SUMMARY OF THE INVENTION

The present invention is to provide an image sensor and a method of fabricating the same, which can improve optical performance and alleviate the cross-talk phenomenon.

The present invention provides an image sensor, which includes a plurality of photodiode doped regions in a substrate, a passivation layer above the substrate, a dielectric layer between the substrate and the passivation layer, and a plurality of color filters in the dielectric layer being corresponding to the photodiode doped regions.

According to an embodiment of the present invention, the above-mentioned color filters are disposed in the dielectric layer at substantially same height. The color filters are disposed in the dielectric layer at the position adjacent to the substrate surface, at the position adjacent to the passivation layer, or at the position not contacting the passivation layer and the substrate in the dielectric layer.

According to an embodiment of the present invention, the above-mentioned color filters are disposed in the dielectric layer at different height. The color filters are disposed in the dielectric layer at the position adjacent to the substrate surface, and at the position adjacent to the passivation layer, or at the position not contacting the passivation layer and the substrate, respectively.

According to an embodiment of the present invention, at least one of the above-mentioned color filters comprises at least one first color filter and a second color filter being correspondingly disposed in the dielectric layer at different heights respectively.

According to an embodiment of the present invention, the above-mentioned image sensor further comprises an anti-reflective coating disposed between the substrate and the dielectric layer. In addition, it further comprises a plurality of micro lenses disposed above the passivation layer being corresponding to photodiode doped regions.

According to an embodiment of the present invention, the above-mentioned dielectric layer comprises an inner dielectric layer and an inter-metal dielectric layer, and the color filters are disposed in the inner dielectric layer, in the inter-metal dielectric layer, or in the inner dielectric layer and the inter-metal dielectric layer.

According to an embodiment of the present invention, the material of the above-mentioned color filters is inorganic material.

The present invention provides a method of fabricating an image sensor. First, a plurality of photodiode doped regions is formed in a substrate. Then, a dielectric layer and a plurality of color filters being corresponding to the photodiode doped regions are formed on the substrate. After the dielectric layer and the color filters are formed, a passivation layer is formed on the dielectric layer.

According to an embodiment of the present invention, the above-mentioned step of forming the dielectric layer and color filters on the substrate comprises forming a plurality of first color filters on the substrate being corresponding to photodiode doped regions, and then forming a first dielectric layer around the first color filters.

According to an embodiment of the present invention, the above-mentioned method of fabricating an image sensor further comprises forming a plurality of second color filters on the first dielectric layer to correspond to and align with the first color filters, and forming a second dielectric layer around the second color filters.

According to an embodiment of the present invention, the above-mentioned step of forming the dielectric layer and color filters on the substrate comprises the following steps. First, at least one first color filter is formed on the substrate being corresponding to one of the photodiode doped regions. Then, a first dielectric layer is formed around the first color filter. Thereafter, at least one second color filter is formed on the first dielectric layer being corresponding to another one of the photodiode doped regions. After that, a second dielectric layer is formed on the first dielectric layer to cover around the second color filter.

According to an embodiment of the present invention, the above-mentioned step of forming the dielectric layer and color filters on the substrate comprises forming a first dielectric layer on the substrate, and forming a plurality of first openings in the first dielectric layer being corresponding to the photodiode doped regions, and then forming a plurality of first color filters in the first openings.

According to an embodiment of the present invention, the above-mentioned method of fabricating an image sensor further comprises forming a second dielectric layer on the first dielectric layer, and a plurality of second openings in the second dielectric layer being to correspond to and align with the first color filters, and then forming a plurality of second color filters in the second openings.

According to an embodiment of the present invention, the above-mentioned step of forming the dielectric layer and color filters on the substrate comprises the following steps. First, a first dielectric layer is formed on the substrate, and at least one first opening is formed in the first dielectric layer being corresponding to one of the photodiode doped regions. Then, a first color filter is formed in the first opening. Thereafter, a second dielectric layer is formed on the substrate, and at least one second opening is formed in the second dielectric layer being corresponding to another one of the photodiode doped regions. After that, a second color filter is formed in the second opening.

According to an embodiment of the present invention, the material of the above-mentioned color filters is inorganic material.

According to an embodiment of the present invention, the above-mentioned method of fabricating an image sensor comprises forming an anti-reflective coating on the substrate before forming the color filters and the dielectric layer, and further comprises forming a plurality of micro lenses on the passivation layer being to correspond to and align with the photodiode doped regions.

The color filters of the image sensor of the present invention are disposed below the passivation layer, so that the optical performance can be improved and the cross-talk phenomenon can be alleviated.

In order to the make aforementioned and other objects, features and advantages of the present invention comprehensible, preferred embodiments accompanied with figures are described in detail below.

### BRIEF DESCRIPTION OF THE DRAWINGS

FIG. 1 is a schematic partial sectional view of an image sensor according to an embodiment of the present invention.

FIG. 2 is a schematic partial sectional view of an image sensor according to another embodiment of the present invention.

FIG. 3 is a schematic partial sectional view of an image sensor according to another embodiment of the present invention.

FIG. 4 is a schematic partial sectional view of an image sensor according to another embodiment of the present invention.

FIG. 5 is a schematic partial sectional view of an image sensor according to another embodiment of the present invention.

FIG. 6 is a schematic partial sectional view of an image sensor according to another embodiment of the present invention.

FIG. 7 is a schematic partial sectional view of an image sensor according to another embodiment of the present invention.

FIG. 8 is a schematic partial sectional view of an image sensor according to another embodiment of the present invention.

FIG. 9 is a schematic partial sectional view of an image sensor according to another embodiment of the present invention.

FIGS. 10A to 10B are sectional views of the partial processes of a method of fabricating the image sensor according to an embodiment of the present invention.

FIG. 11 is a schematic partial sectional view of an image sensor according to another embodiment of the present invention.

FIGS. 12A to 12B are sectional views of the partial processes of another method of fabricating the image sensor according to another embodiment of the present invention.

FIG. 13 is a schematic partial sectional view of an image sensor according to another embodiment of the present invention.

### DESCRIPTION OF EMBODIMENTS

The color filter of the image sensor of the present invention is disposed in the dielectric layer below the passivation layer. Compared with the color filter being disposed above the passivation layer in the conventional art, the color filter of the image sensor of the present invention is near the photodiode doped regions, thus having a high optical performance and alleviating the cross-talk phenomenon. Several embodiments are described below to illustrate the implementation configuration of the present invention in detail. In the following embodiments, the color filter can be color filters of the same color or color filters of different colors.

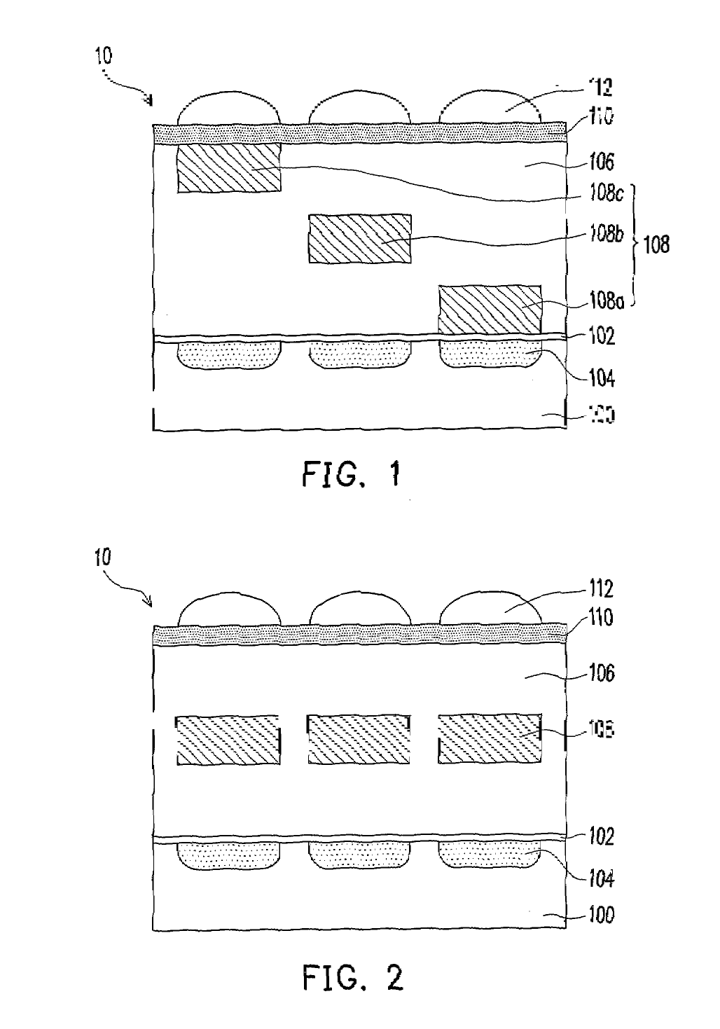

Referring to FIG. 1, an image sensor 10 of an embodiment of the present invention is, for example, a CMOS image sensor or a contact image sensor, but is not limited to this. The image sensor 10 includes photodiode doped regions 104, a dielectric layer 106, color filters 108 and a passivation layer 110. The photodiode doped regions 104 are disposed in a substrate 100. The dielectric layer 106 is disposed between the substrate 100 and the passivation layer 110. The color filters 108 are disposed in the dielectric layer 106. The color filters 108 can be constituted of a single-layer film or a multilayer film. The single-layer film is, for example, a layer of inorganic membrane such as silicon nitride layer, silicon oxynitride layer or amorphous silicon layer. The multilayer film is, for example, a stacked layer of multiple layers of inorganic material, for example, a stacked layer of titanium dioxide and silicon oxide or a stacked layer of tantalum pentoxide and silicon oxide.

In addition to the above-mentioned means, an anti-reflective coating 102 can also be disposed between the substrate 100 and the dielectric layer 106. In addition, in an embodiment, micro lenses 112 are further disposed on the passivation layer 110.

In accordance with the requirements of products, the color filters 108 can be disposed in the dielectric layer 106, referring to color filter 108a adjacent to the surface of the substrate 100, or, referring to color filter 108c adjacent to the passivation layer 110, or, referring to color filter 108b not contacting the passivation layer 110 and the substrate 100.

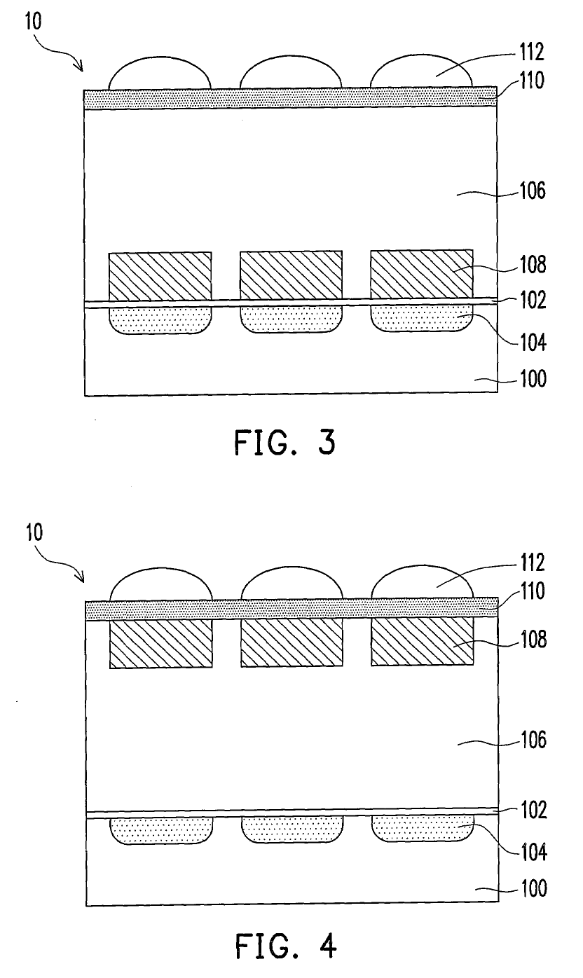

In an embodiment, the color filters 108 are disposed in the dielectric layer 106 at different heights, as shown in FIG. 1. In another embodiment, the color filters 108 are disposed in the dielectric layer 106 at substantially same height. The color filters 108 can be disposed in the dielectric layer 106 at the position not contacting the passivation layer 110 and the substrate 100 (as shown in FIG. 2), or at the position adjacent to the surface of the substrate 100 (as shown in FIG. 3), or at the position adjacent to the passivation layer 110 (as shown in FIG. 4).

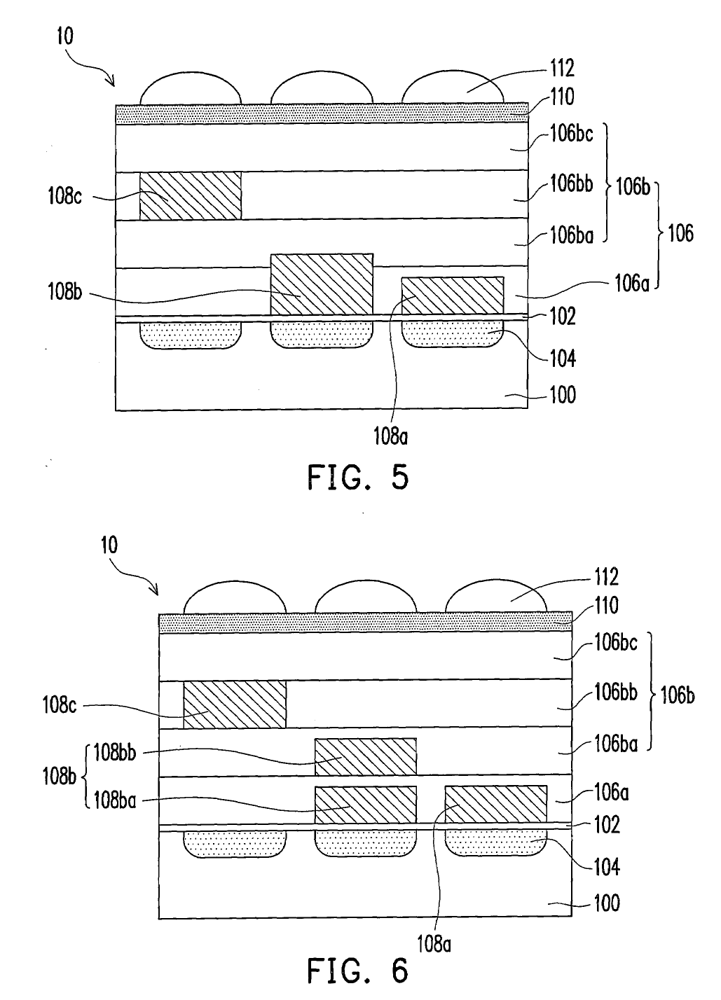

Referring to FIG. 5, in another embodiment, the dielectric layer 106 includes a first dielectric layer 106a and a second dielectric layer 106b. The first dielectric layer 106a is, for example, an inner dielectric layer. The second dielectric layer 106b is, for example, an inter-metal dielectric layer, and can be subdivided into a first inter-metal dielectric layer 106ba, a second inter-metal dielectric layer 106bb and a third inter-metal dielectric layer 106bc. Since the color filters and the first dielectric layer 106a and the second dielectric layer 106b are of different thickness, the color filters are disposed in the first dielectric layer 106a, referring to color filter 108a, in the second dielectric layer 106b, referring to color filter 108c, or in the first dielectric layer 106a and the second dielectric layer 106b, referring to color filter 108b.

Referring to FIG. 5, generally speaking, the thickness of the color filters can be up to 1-2 μm, and the thickness of the first dielectric layer 106a in the dielectric layer 106 is less than 1 μm. During the process, after the color filters and the first dielectric layer 106a are formed, the color filters 108b rise above the surface of the first dielectric layer 106a, such that the subsequently formed second dielectric layer 106b obviously has a rough surface. Referring to FIG. 6, according to the practical requirements, the color filters 108b of FIG. 6 can be divided into two parts 108ba, and 108bb as shown in FIG. 6, or can be divided into more parts, so as to achieve the same filtering effect.

The color filters in the image sensor of the present invention are formed in the dielectric layer below the passivation layer, and the forming method thereof includes first forming patterned color filters, and then forming the dielectric layer. Another method can also be adopted, which includes first forming a dielectric layer on the substrate, and forming openings in the dielectric layer, and then forming the color filters in the openings. The detailed implementation is illustrated with the following embodiments.

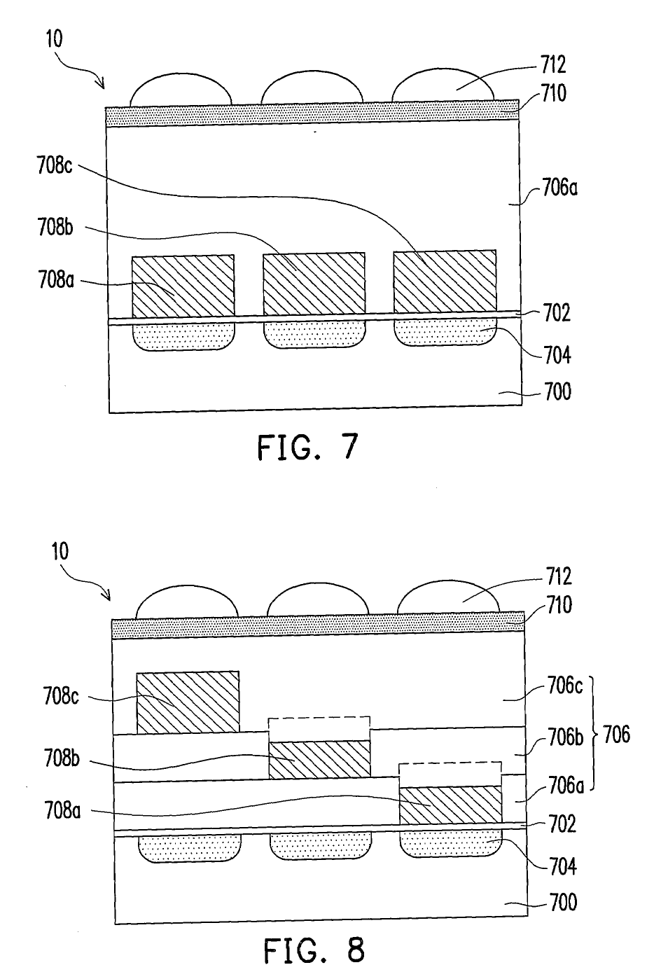

Referring to FIG. 7, a plurality of photodiode doped regions 704 is formed in the substrate 700, and the forming method thereof includes the following steps. First, a patterned photoresist layer (not shown) is formed on the substrate 700. Then, an ion-implantation process is performed with the photoresist layer serving as mask, so as to implant ions into the substrate 700. Thereafter, the photoresist layer is removed. After that, an anti-reflective coating 702 is formed on the substrate 700, in which the material of the anti-reflective coating 702 is, for example, silicon nitride or silicon oxynitride, and the forming method thereof is, for example, chemical vapor deposition. Then, a color filter 708a is formed on the anti-reflective coating 702. The color filter 708a can be formed by patterning a single-layer film or a multilayer film. The single-layer film is, for example, an inorganic membrane such as silicon nitride layer, silicon oxynitride layer or amorphous silicon layer. The multilayer film is, for example, a stacked layer of multiple layers of inorganic material, wherein the stacked layer is, for example, a stacked layer of titanium dioxide and silicon oxide, a stacked layer of tantalum pentoxide and silicon oxide or a stacked layer of niobium pentoxide and silicon oxide. In an embodiment, the evaporation is performed in low temperature, under the conditions that the temperature is 80° C. to 240° C., the pressure is 0.1 millitorr to 10 torr, the introduced gas is oxygen of 10 to 50 sccm and nitrogen of 0 to 50 sccm, the ion source is 100 to 200 volt/1 to 10 ampere(s), so as to form the stacked layer with a loose structure. Then, the stacked layer with loose structure is etched and patterned. After that, an annealing process is performed on the patterned stacked layer in high temperature, such that the structure of the patterned stacked layer becomes compact. In an embodiment, if the process of fabricating the color filters is a front-end process, the annealing temperature is, for example, about 300° C. to 900° C. In another embodiment, if the process of fabricating the color filters is a back-end process, the annealing temperature is, for example, about 300° C. to 400° C. The gas used in the annealing process is one selected from among nitrogen, nitrogen and hydrogen, ammonia gas, ammonia gas and hydrogen. The annealing time is 10 minutes to 4 hours. Since the structure of the stacked layer is loose when being formed in low temperature, and is compact when being formed in high temperature, the etching rate of the stacked layer formed in low temperature is relatively high, thus improving production capacity of the process.

Next, color filters 708b and 708c are formed in sequence. The method of forming the color filters 708b and 708c can also be the same as that described above. After that, a dielectric layer 706a and a passivation layer 710 are formed on the substrate 700. The material of the dielectric layer 706a is, for example, silicon oxide or a low-k material with a dielectric coefficient less than 4, and the forming method thereof is chemical vapor deposition. The passivation layer 710 is constituted of, for example, a silicon oxide layer and silicon nitride layer, and the forming method thereof is chemical vapor deposition. In an embodiment, after the passivation layer 710 is formed, micro lenses 712 can be further formed on the passivation layer 710.

FIG. 8 is a partial schematic view of an image sensor of another embodiment of the present invention.

Referring to FIG. 8, the color filters 708a, 708b and 708c are formed at substantially same height in the above description, but the color filters 708a, 708b and 708c are formed at different heights in the present embodiment. According to the above description, the method of fabricating the image sensor includes the following steps. First, the photodiode doped regions 704, the anti-reflective coating 702, the color filter 708a and the dielectric layer 706a are formed. Then, a color filter 708b is formed on the dielectric layer 706a being corresponding to the photodiode doped regions 704. The material and forming method of the color filter 708b can be the same as those described above. Then, another dielectric layer 706b is formed on the substrate 700. This dielectric layer 706b is, for example, the first inter-metal dielectric layer. The material and forming method of the dielectric layer 706b can be the same as those described above. Then, a color filter 708c is formed on the dielectric layer 708b. The material and forming method of the color filter 708c can be the same as those described above. After that, another dielectric layer 706c is formed on the substrate 700. The dielectric layer 706c is, for example, the second inter-metal dielectric layer. The forming method of the dielectric layer 706c can be the same as that described above. Then, a passivation layer 710 is formed on the dielectric layer 706c. In an embodiment, micro lenses 712 can be further formed after the passivation layer 710 is formed.

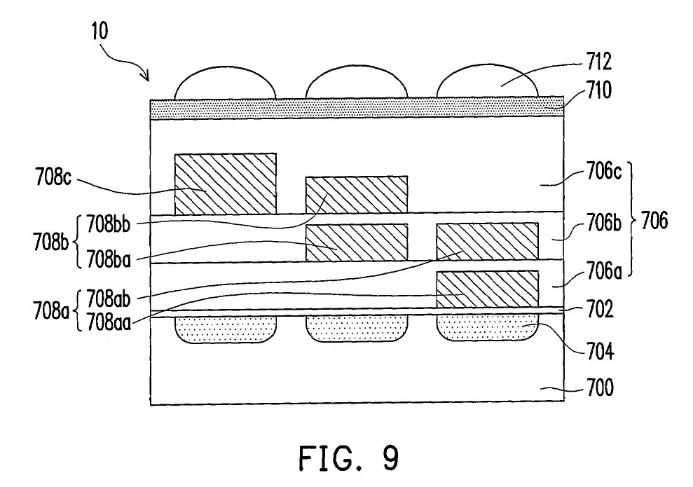

In the above-mentioned fabricating method of FIG. 8, if the thickness of color filters 708a, and 708b (indicated by dashed line) is larger than the thickness of dielectric layers 706a, and 706b, the subsequently formed dielectric layers 706b, and 706c obviously have a rough surface. If the roughness causes problems in lithography, according to the practical requirements, the color filters 708a and 708b of FIG. 8 are respectively divided into two parts 708aa, 708ab and 708ba, 708bb, as shown in FIG. 9, or are respectively divided into more parts, so as to achieve the same filtering effect.

Referring to FIG. 9, the method of fabricating the image sensor 10 includes the following steps. First, the photodiode doped regions 704 and the anti-reflective coating 702 can be formed the same as that described above. Then, a color filter 708a is formed on the anti-reflective coating 702, and then the dielectric layer 706a is formed. After that, color filters 708ab and 708ba are respectively formed on the dielectric layer 706a being corresponding to the photodiode doped regions 704. Thereafter, another dielectric layer 706b, e.g. the first inter-metal dielectric layer, is formed on the substrate 700. The material and forming method of the dielectric layer 706b can be the same as those described above. Then, color filters 708bb and 708c are respectively formed on the dielectric layer 708b. The material and forming method of color filters 708aa, 708ab, 708ba, 708bb, 708c can be the same as those described above. After that, another dielectric layer 706c and the passivation layer 710 are formed on the substrate 700. In an embodiment, the micro lenses 712 can be further formed after the passivation layer 710 is formed.

The above-mentioned method of forming the image sensor includes first forming the patterned color filters, and then forming the dielectric layer. Another method is described with reference to the following embodiment, which includes first forming the dielectric layer on the substrate, and forming openings in the dielectric layer, and then forming the color filters in the openings.

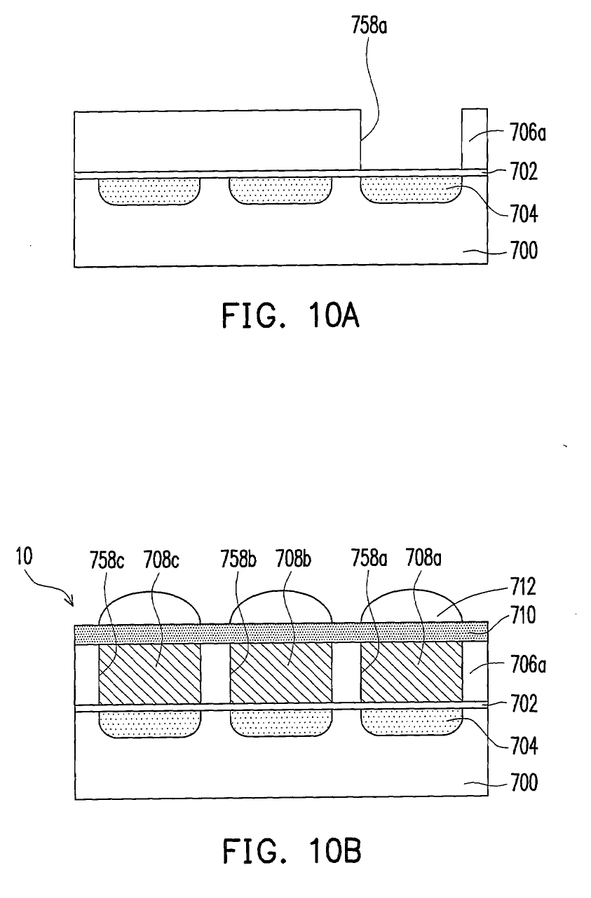

FIGS. 10A to 10B are sectional views of the processes of a method of fabricating the image sensor according to an embodiment of the present invention.

Referring to FIG. 10A, according to the above method, the photodiode doped regions 704 and the anti-reflective coating 702 are formed. Then, the dielectric layer 706a is formed, and the lithographic process and etching process are performed to form an opening 758a in the dielectric layer 706a being corresponding to the photodiode doped regions 704.

Then, referring to FIG. 10B, a color filter 708a is formed in the opening 758a, and the forming method thereof includes the following steps. First, a color filter film layer is formed on the substrate 700, which is filled in the opening 758a and covers the dielectric layer 706a. Then, an etch-back process is performed to remove the film layer covering the dielectric layer 706a. Thereafter, an opening 758b is formed in the dielectric layer 706a, and a color filter 708b is formed in the opening 758b. After that, an opening 758c is formed in the dielectric layer 706a, and a color filter 708c is formed in the opening 758c. Thereafter, a passivation layer 710 is formed on the substrate 700. In an embodiment, the micro lenses 712 can be further formed after the passivation layer 710 is formed.

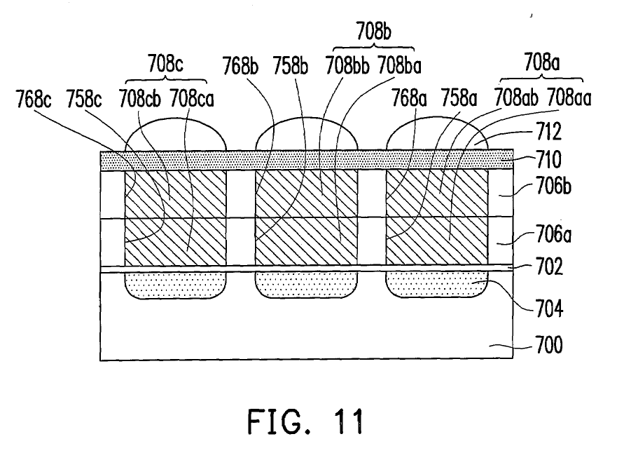

In the above-mentioned method, if the thickness of color filters 708a, 708b is larger than the thickness of the dielectric layer, the color filters are divided into two parts of the color filter 708aa, 708ab, 708ba, 708bb, and 708ca, 708cb, so as to accomplish the process, as shown in FIG. 11.

Referring to FIG. 11, according to the above method, the photodiode doped regions 704 and the anti-reflective coating 702 are formed. Then, the first parts of color filter 708aa, 708ba, 708ca are respectively formed in the dielectric layer 706a. After that, the dielectric layer 706b is formed on the substrate 700, and openings 768a, 768b, 768c are respectively formed in the dielectric layer 706b, and then the second parts of color filter 708ab, 708bb, 708cb are respectively formed in the openings 768a, 768b, 768c. Thereafter, the passivation layer 710 is formed on the substrate 700.

In the above embodiments, for example, the heights of color filters are substantially the same and the color filters are formed in a single dielectric layer. However, the present invention is not limited to this. The color filters of the present invention can also be formed in the dielectric layer at different heights.

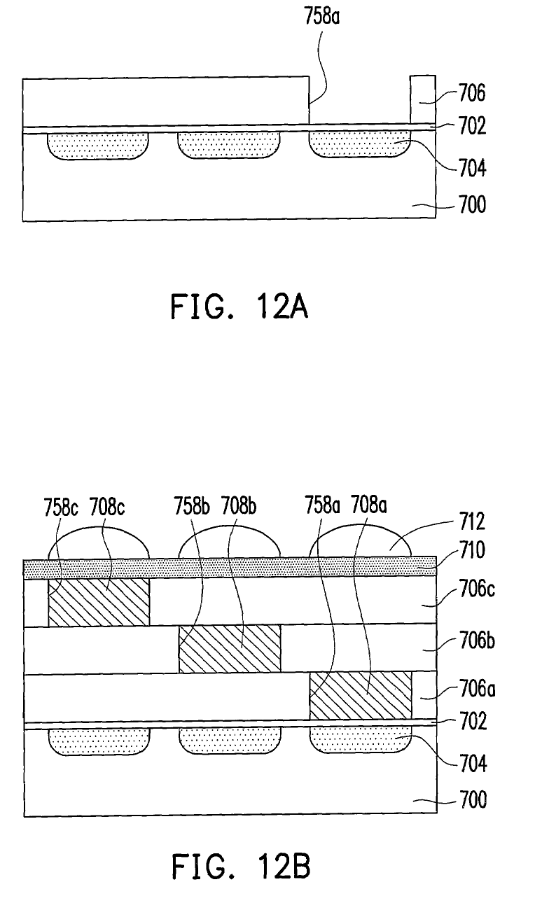

FIGS. 12A to 12B are sectional views of the processes of a method of fabricating the image sensor according to an embodiment of the present invention.

Referring to FIG. 12A, according to the above method, the photodiode doped regions 704 and the anti-reflective coating 702 are formed. Then, the dielectric layer 706a is formed, and the lithographic process and etching process are performed to form an opening 758a in the dielectric layer 706a being corresponding to the photodiode doped regions 704.

Then, referring to FIG. 12B, a color filter 708a is formed in the opening 758a, and the forming method thereof includes the following steps. First, a color filter film layer is formed on the substrate 700, which is filled in the opening 758a and covers the dielectric layer 706a. Then, the etch-back process is performed to remove the film layer covering the dielectric layer 706a. After that, the dielectric layer 706b is formed, and an opening 758b is formed therein, and then a color filter 708b is formed in the opening 758b. Thereafter, the dielectric layer 706c is formed, and an opening 758c is formed therein, and then a color filter 708c is formed in the opening 758c; Then, a passivation layer 710 is formed on the substrate 700. In an embodiment, the micro lenses 712 can be further formed after the passivation layer 710 is formed.

Likewise, in the above method, if the thickness of color filters 708a, 708b is larger than the thickness of dielectric layers 706a, 706b, the color filters are divided into two parts of the color filter 708aa, 708ab and 708ba, 708bb, so as to accomplish the process.

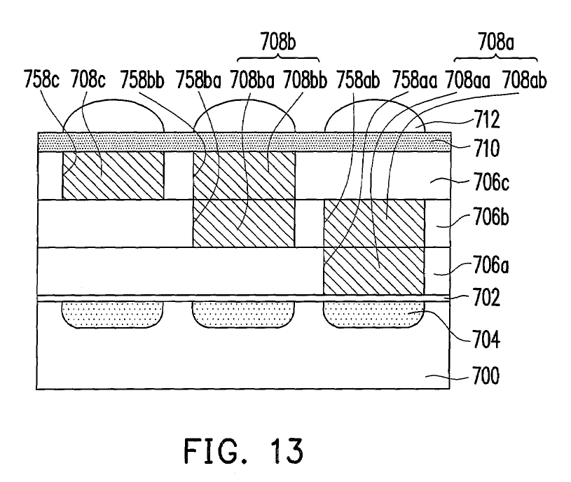

Referring to FIG. 13, the photodiode doped regions 704, the anti-reflective coating 702, and the dielectric layer 706a are formed according to the above method. Then, an opening 758aa is formed in the dielectric layer 706a, and the first part of color filter 708aa is formed in the opening. After that, the dielectric layer 706b is formed on the substrate 700, and an opening 758ab is formed in the dielectric layer 706b, and then the second part of color filter 708ab is formed in the opening 758ab. Thereafter, an opening 758ba is formed in the dielectric layer 706b, and the first part of color filter 708ba is formed in the opening 758ba. Then, the dielectric layer 706c is formed on the substrate 700, and an opening 758bb is formed in the dielectric layer 706c, and the second part of color filter 708bb is formed in the opening 758bb. After that, an opening 758c is formed in the dielectric layer 706c, and the color filter 708c is formed in the opening 758c. In an embodiment, the micro lenses 712 can be further formed after the passivation layer 710 is formed.

Since the color filters of the image sensor of the present invention are disposed below the passivation layer, the light transmittance can be improved and the cross-talk phenomenon can be alleviated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An image sensor comprising:
a plurality of photodiode doped regions disposed in a substrate;
a passivation layer disposed above the substrate;
a dielectric layer disposed between the passivation layer and the substrate and covering the photodiode doped regions; and
a plurality of color filters disposed in the dielectric layer and being corresponding to the photodiode doped regions.

2. The image sensor as claimed in claim 1, wherein the color filters are disposed in the dielectric layer at substantially same height.

3. The image sensor as claimed in claim 2, wherein the color filters are disposed in the dielectric layer adjacent to the substrate surface.

4. The image sensor as claimed in claim 2, wherein the color filters are disposed in the dielectric layer adjacent to the passivation layer.

5. The image sensor as claimed in claim 2, wherein the color filters are disposed in the dielectric layer not contacting the passivation layer and the substrate.

6. The image sensor as claimed in claim 1, wherein the color filters are disposed in the dielectric layer at different height.

7. The image sensor as claimed in claim 1, wherein the color filters are disposed in the dielectric layer at the position adjacent to the substrate surface, at the position adjacent to the passivation layer, and at the position not contacting the passivation layer and the substrate, respectively.

8. The image sensor as claimed in claim 1, wherein at least one of the color filters comprises at least one first color filter and at least one second color filter being disposed in the dielectric layer at different height respectively and being corresponding to the same photodiode doped region.

9. The image sensor as claimed in claim 1, further comprising an anti-reflective coating disposed between the substrate and the dielectric layer.

10. The image sensor as claimed in claim 1, wherein the dielectric layer comprises an inner dielectric layer and an inter-metal dielectric layer, and the color filters are disposed in the inner dielectric layer, in the inter-metal dielectric layer, or between the inner dielectric layer and the inter-metal dielectric layer.

11. The image sensor as claimed in claim 1, wherein the material of the color filters is inorganic material.

12. The image sensor as claimed in claim 1, further comprising a plurality of micro lenses disposed on the passivation layer and being corresponding to the photodiode doped regions.

13. A method of fabricating an image sensor comprising:
forming a plurality of photodiode doped regions in a substrate;
forming a dielectric layer and a plurality of color filters on the substrate, wherein the color filters are corresponding to the photodiode doped regions; and
after the dielectric layer and the color filters are formed, forming a passivation layer on the dielectric layer.

14. The method of fabricating the image sensor as claimed in claim 13, wherein the step of forming the dielectric layer and the color filters on the substrate comprises:
forming a plurality of first color filters on the substrate being corresponding to the photodiode doped regions; and
forming a first dielectric layer around the first color filters.

15. The method of fabricating the image sensor as claimed in claim 14, further comprising:
forming a plurality of second color filters on the first dielectric layer to correspond to and align with the first color filters; and
forming a second dielectric layer around the second color filters.

16. The method of fabricating the image sensor as claimed in claim 14, wherein the step of forming the dielectric layer and the color filters on the substrate comprises:
forming at least one first color filter on the substrate being corresponding to one of the photodiode doped regions;
forming a first dielectric layer around the first color filter;
forming at least one second color filter on the first dielectric layer being corresponding to another one of the photodiode doped regions; and
forming a second dielectric layer on the first dielectric layer to cover around the second color filter.

17. The method of fabricating the image sensor as claimed in claim 13, wherein the step of forming the dielectric layer and the color filters on the substrate comprises:
forming a first dielectric layer on the substrate,
forming a plurality of first openings in the first dielectric layer to correspond to the photodiode doped regions; and
forming a plurality of first color filters in the first openings.

18. The method of fabricating the image sensor as claimed in claim 17, further comprising:
forming a second dielectric layer on the substrate to cover the first color filters and the first dielectric layer;
forming a plurality of second openings in the second dielectric layer to correspond to and align with the first color filters; and
forming a plurality of second color filters in the second openings.

19. The method of fabricating the image sensor as claimed in claim 13, wherein the step of forming the dielectric layer and the color filters on the substrate comprises:
forming a first dielectric layer on the substrate;
forming at least one first opening in the first dielectric layer to correspond to one of the photodiode doped regions;
forming a first color filter in the first opening;
forming a second dielectric layer on the substrate to cover the first dielectric layer and the first color filter;
forming at least one second opening in the dielectric layer to correspond to another one of the photodiode doped regions; and
forming a second color filter in the second opening.

20. The method of fabricating the image sensor as claimed in claim 13, wherein the material of the color filters is inorganic material.

21. The method of fabricating the image sensor as claimed in claim 13, further comprising forming an anti-reflective coating on the substrate before forming the color filters and the dielectric layer.

22. The method of fabricating the image sensor as claimed in claim 13, further comprising forming a plurality of micro lenses on the passivation layer to correspond to and align with the photodiode doped regions.
